(19) United States
(12) Patent Application Publication
(10) Pub. No.: US 2018/0047582 A1
(43) Pub. Date: Feb. 15, 2018

(54) Semiconductor Device and Method of Manufacturing the Semiconductor Device

(71) Applicant: Infineon Technologies Dresden GmbH, Dresden (DE)

(72) Inventors: Marko Lemke, Dresden (DE); Alfred Vater, Dresden (DE); Carsten Moritz, Radeberg (DE)

(21) Appl. No.: 15/671,228

(22) Filed: Aug. 8, 2017

(30) Foreign Application Priority Data
Aug. 12, 2016 (DE) 102016115008.8

(51) Int. Cl. H01L 21/311; H01L 21/308; H01L 29/66; B81C 1/00; H01L 29/06; H01L 29/08; H01L 29/10; H01L 21/306; H01L 29/78

(52) U.S. Cl. CPC H01L 21/31144; H01L 21/30604; H01L 21/308; H01L 21/31111; H01L 29/66704; H01L 29/7825; H01L 29/0696; H01L 29/0865; H01L 29/0882; H01L 29/1095; B81C 1/00928

(57) ABSTRACT

A method of manufacturing a semiconductor device includes forming an etching mask over a semiconductor body, forming a plurality of trenches in the semiconductor body to define a plurality of protruding semiconductor portions between adjacent trenches, and forming a protection layer in contact with a semiconductor material of the protruding semiconductor portions. The method further includes performing a wet etching step to remove portions of the etching mask and, thereafter, treating the semiconductor body with a mixture of hydrofluoric acid and ethylene glycol and bringing the semiconductor material of sidewalls of the plurality of protruding semiconductor portions into contact with the mixture of hydrofluoric acid and ethylene glycol.

### BACKGROUND

Power transistors commonly employed in automotive and industrial electronics require a low on-state resistance (Rₒₙ×A) while securing a high voltage blocking capability. For example, a MOS (“metal oxide semiconductor”) power transistor should be capable, depending upon application requirements, to block drain-to-source voltages V_{ds} of some tens to some hundreds or thousands volts. MOS power transistors typically conduct very large currents which may be up to some hundreds of amperes at typical gate-source voltages of about 2 to 20 V.

Power switching devices have been developed to achieve the desired voltage blocking capability in the off-state, while achieving a low Rdsₒₙ in the on-state in the same piece of silicon.

According to concepts, a power transistor may be implemented by an ADZFET (“active drift zone field effect transistor”). ADZFETs use cascades of basic elements to achieve any desired value of a breakdown voltage and any desired value of Rdson, just by choosing the number of elements which are connected parallel to each other (Rdson) and of elements which are serially connected to each other (breakdown voltage).

A basic element of such an ADZFET is a vertical FinFET device using a silicon structure having a very high aspect ratio. It has been found that problems of sticking of silicon structures having a very high aspect ratio may arise.

### SUMMARY

According to an embodiment, a method of manufacturing a semiconductor device comprises forming an etching mask over a semiconductor body and forming a plurality of trenches in a semiconductor body thereby defining a plurality of protruding semiconductor portions between adjacent trenches. The method further comprises forming a protection layer in contact with a semiconductor material of the protruding semiconductor portions and performing a wet etching step to remove portions of the etching mask. The method comprises, thereafter, treating the semiconductor body with a mixture of hydrofluoric acid and ethylene glycol and bringing the semiconductor material of sidewalls of the plurality of protruding semiconductor portions into contact with the mixture of hydrofluoric acid and ethylene glycol.

According to an embodiment, a semiconductor device is manufactured by the method as defined above.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1G illustrate a method of manufacturing a semiconductor device according to an embodiment.

FIGS. 2A to 2F illustrate a method of manufacturing a semiconductor device according to a further embodiment.

FIG. 3 summarizes a method according to an embodiment.

FIG. 4 shows an example of a semiconductor device which may be manufactured using the described method.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The terms “wafer”, “substrate” or “semiconductor substrate” used in the following description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide. According to other embodiments, silicon carbide (SiC) or gallium nitride (GaN) may form the semiconductor substrate material. The term “semiconductor body” is intended to mean a semiconductor substrate or any other, e.g. polycrystalline or amorphous semiconductor layer over a suitable carrier.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

The Figures and the description may illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations. In the Figures and the description, for the sake of a better comprehension, often the doped portions are designated as being “p” or “n”-doped. As is clearly to be understood, this designation is by no means intended to be limiting. The doping type can be arbitrary as long as the described functionality is achieved. Further, in all embodiments, the doping types can be reversed.

As will be discussed in the following, a method of manufacturing a semiconductor device comprises forming a plurality of trenches 150, 250 in a semiconductor body 100, 200, thereby defining a plurality of protruding semiconductor portions 160, 260 between adjacent trenches 150, 250.

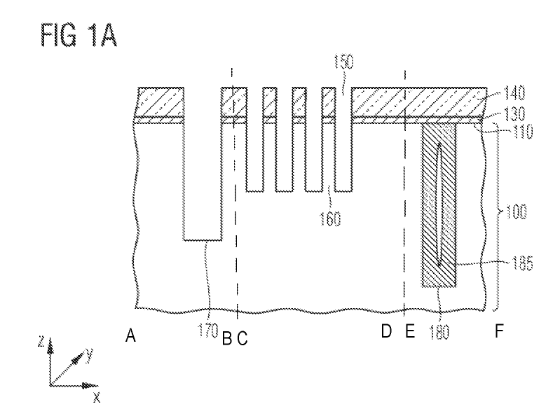

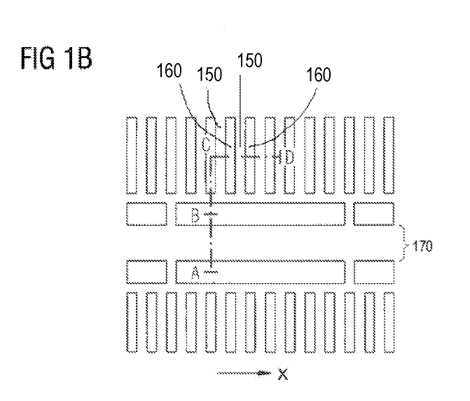

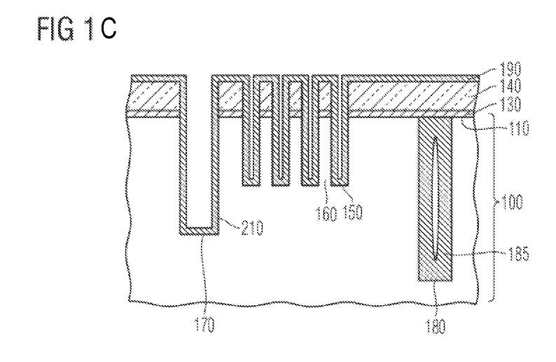

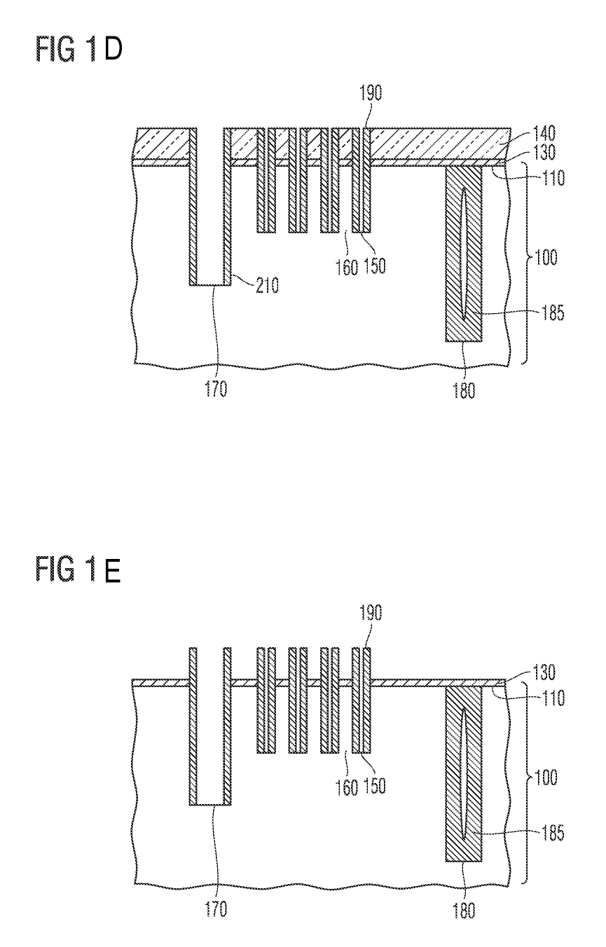

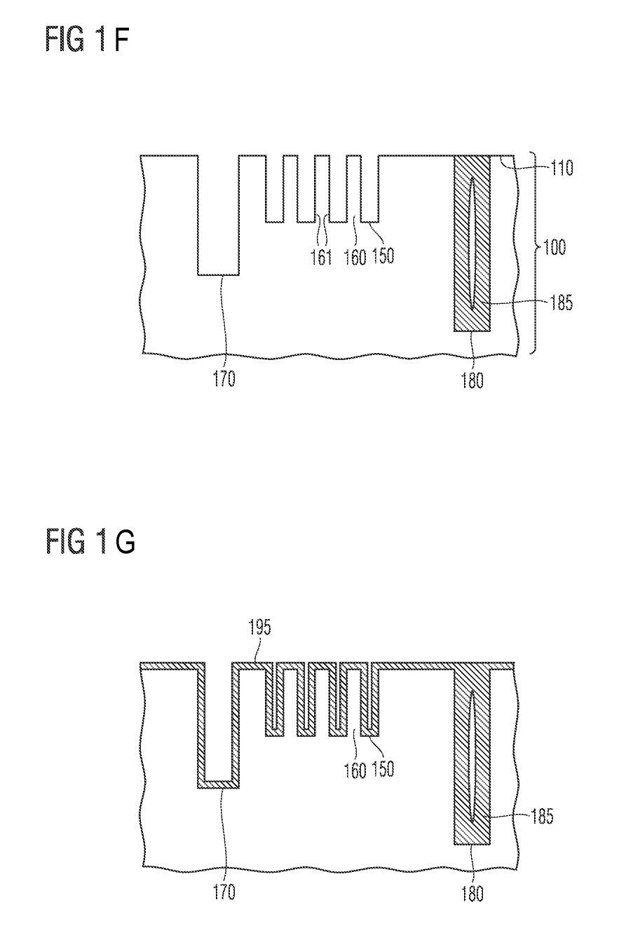

FIG. 1A shows a semiconductor body 100 comprising a plurality of trenches 150. The cross-sectional view between C and D is taken along a first direction, e.g. the x-direction. The trenches 150 may have a longitudinal axis extending in a second direction, e.g. the y-direction. The semiconductor device may further comprise a first groove 170 having a longitudinal axis running in the first direction, e.g. in a plane before or behind the depicted plane of the drawing. The cross-sectional view between A and B is taken along the second direction. The positions of the cross-sectional views can be taken from FIG. 1B showing an example of a layout of a semiconductor device. Protruding portions 160 may be defined between adjacent trenches 150. For example, the protruding portions 160 may be implemented as ridges, e.g. when there are no trenches running in the first direction. According to further embodiments, the protruding portions 160 may form columns which are arranged between adjacent trenches running in the first direction. FIG. 1A further shows a second groove 180 which may surround the array of trenches 150.

For example, a depth of the trenches 150 (or a height of the protruding portions 160) may be more than 500 nm, e.g. more than 1000 nm, e.g. 1000 to 2000 nm. Further, a width of the protruding portions 160, the width being measured along the first direction may be less than 100 nm, e.g. less than 70 nm. For example, the width may be between 20 and 80 nm, e.g. 30 to 70 nm. For example, an aspect ratio, i.e. a ratio of height to width may be more than 10, e.g. more than 20 and further more than 25 or 30. Usually, the trenches 150 may be formed by etching. For example, an etching mask may be formed over the semiconductor body 100. The etching mask may for example comprise a resist mask, e.g. a photoresist mask or a hard mask comprising silicon oxide, silicon nitride, carbon or a combination of these materials or masks. The trenches may be formed by etching using an appropriate etching mask. Generally, when manufacturing a semiconductor device, more than 1000, e.g. more than 10⁵ trenches may be formed with protruding portions being arranged between. For example, a photoresist mask may be patterned using photolithographic processes.

When a correspondingly processed wafer is handled, problems may occur that adjacent protruding portions 160 stick together. For example, when the wafer is handled or moved or exposed to external forces such as an electrostatical charging, or processed, e.g. using liquids, e.g. etched, the protruding portions 160 may stick together. In particular, the capillary forces may result in sticking of the protruding portions, and it may be hard to separate them later.

FIG. 1A shows an example of a workpiece after defining trenches 150 in the semiconductor body 100. The workpiece may further comprise a first groove 170 which may have a deeper depth and a larger width when the trenches 150. The first groove 170 may extend in the first direction. The workpiece further comprises a second groove 180 which may be filled with an insulating material 185 such as silicon oxide. For example, the second groove 180 may surround the array of trenches 150. A first hard or etching mask layer 130 which may comprise silicon nitride may be formed over the first main surface 110 of the semiconductor body. A second hard or etching mask layer 140 which may comprise silicon oxide may be formed over the first hard mask layer 130. According to a further example, the second etching mask layer may be a resist or photoresist mask. For example, the material of the second hard mask layer 140 may be removable using a wet etching process. As has been mentioned above, when applying a wet process to the workpiece problems with sticking may occur. According to further embodiments, the etching mask may comprise a single material, e.g. a photoresist material.

According to an embodiment, a thin silicon nitride layer 190 is formed over the surface of the workpiece shown in FIG. 1A. For example, the silicon nitride layer 190 may be formed by an LPCVD (“low pressure chemical vapour deposition”) method. For example, the silicon nitride layer 190 may have a thickness which is appropriate so as to only cover the sidewalls of the trenches 150. In more detail, a thickness of the silicon nitride layer 190 is smaller than half the width of the trenches 150. For example, when the trenches have a width of more than 100 nm and less than 200 nm, e.g. 110 nm, the silicon nitride layer 190 has a thickness of less than 50 nm, e.g. less than 40 nm, e.g. 20 to 30 nm, for example, 20 to 25 nm.

FIG. 1C shows an example of a resulting structure. As is shown, the silicon nitride layer 190 is conformally arranged over the workpiece. In more detail, the silicon nitride layer 190 covers the sidewalls, while maintaining the shape of the trenches 150. Thereafter, an anisotropic etching method is performed, e.g. a dry etching method for removing the horizontal portions of the silicon nitride layer 190.

FIG. 1D shows an example of a resulting structure. As is shown, a horizontal portion of the silicon nitride layer 190 is removed. In particular, the silicon nitride layer 190 is removed from a bottom side of the trenches 150 and the second hard or etching mask layer 140 is uncovered. Thereafter, the second hard or etching mask layer 140 is removed. For example, when the second hard or etching mask layer comprises silicon oxide, this may be accomplished using hydrofluoric acid.

FIG. 1E shows an example of a resulting structure. As is shown, the second hard or etching mask layer 140 is removed from the surface of the workpiece. Since the filling 185 inside the second groove 180 is protected by the first hard or etching mask layer 130, the silicon oxide 185 in the second groove 180 will not be etched. Due to the presence of the silicon nitride layer 190 arranged on the sidewalls of the trenches 150, sticking of the protruding portions 160 during a wet etching process is avoided or suppressed.

Thereafter, the workpiece is treated with a mixture of hydrofluoric acid (HF) and ethylene glycol. In particular, a ratio of ethylene glycol to HF may be more than 90:10, e.g. from 90:10 to 99:1, e.g. 96:4. By suitably setting the time and the temperature of the mixture, the etching rate of etching silicon nitride may be determined. The time and the temperature are set so that mainly the silicon nitride is removed from a resulting surface of the workpiece, while substantially maintaining the silicon body material.

FIG. 1F shows an example of a resulting structure. As is shown, the silicon nitride layer, in particular, the first hard or etching mask layer 130 is completely removed from the workpiece. Further, due to this treatment, sidewalls 161 of the protruding portions 160 are brought into contact with the mixture of hydrofluoric acid and ethylene glycol. Thereafter, an oxide layer 195 may be formed over the resulting surface. For example, the silicon oxide layer 195 may be formed by a thermal oxidation method, a CVD (“chemical vapour deposition”) method, e.g. using TEOS (“tetraethyl ortho silicate”) as a starting material or a combination of these methods. FIG. 1G shows an example of a resulting structure.

After forming the silicon oxide layer 195, the protruding portions 160 are protected from sticking together. In particular, it has been found that due to the presence of the thin silicon nitride layer 190 which leaves spaces between adjacent ridges uncovered to form a slit, the mixture of hydrofluoric acid and ethylene glycol may be employed so as to remove the silicon nitride layer 190. The mixture of hydrofluoric acid and ethylene glycol further passivates the silicon surface and avoids the occurrence of van de Waals bonding between adjacent ridges. As a result, sticking may be avoided or suppressed.

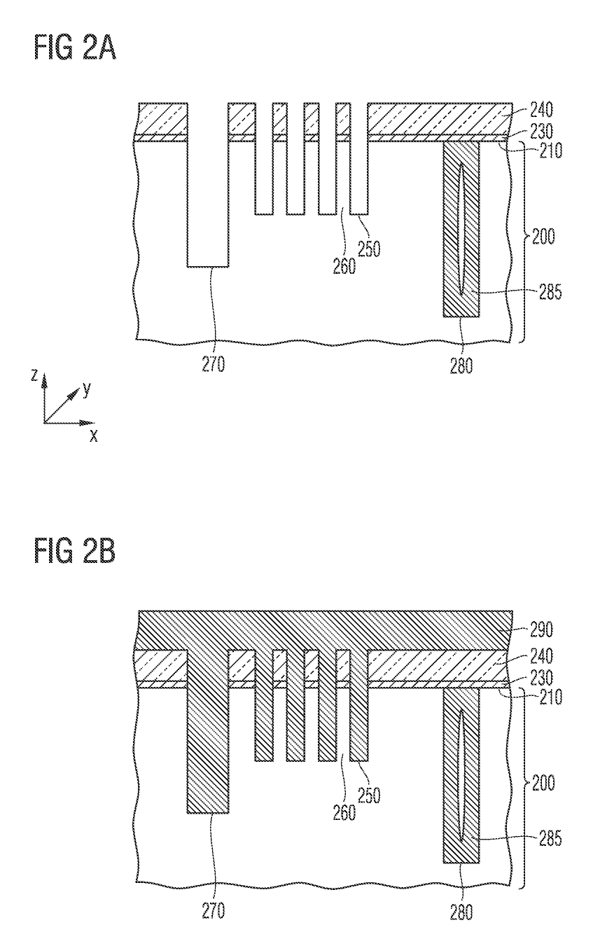

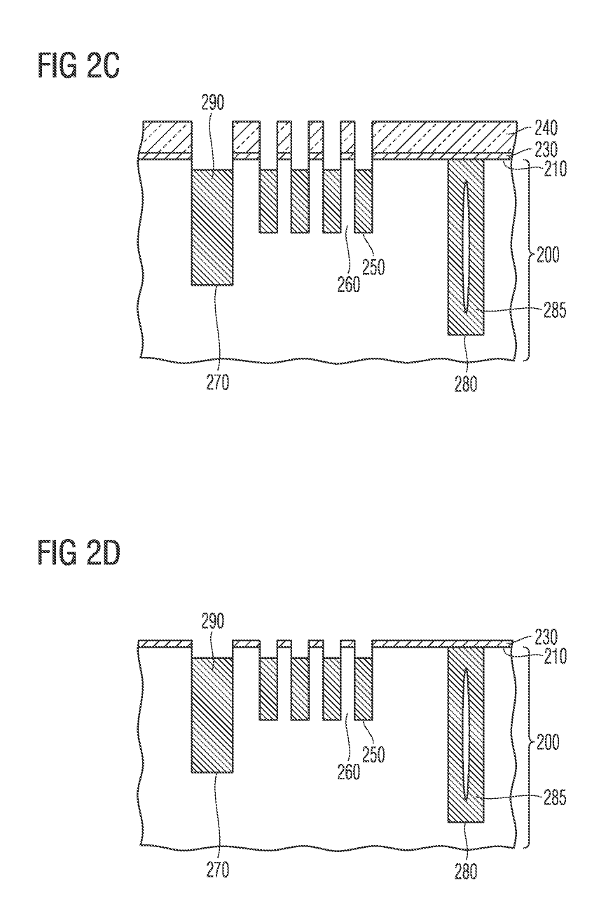

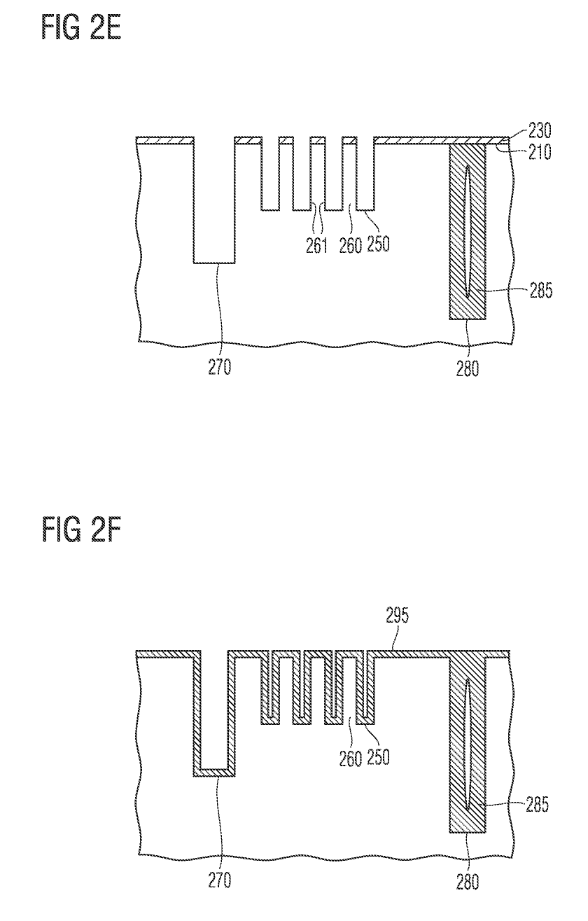

FIGS. 2A to 2F illustrate a method according to a further embodiment. It is to be noted that basically the same components as those illustrated in FIGS. 1A to 1G are shown in FIGS. 2A to 2F, the reference numeral being incremented by “100” unless otherwise indicated.

FIG. 2A shows a workpiece for starting the method according to the further embodiment. In particular, the workpiece of FIG. 2A is identical with the workpiece of FIG. 1A, so that a description thereof is omitted for the sake of convenience.

Thereafter, a resist material 290 is formed over a surface of the workpiece. In particular, the resist material 290 completely fills any of the trenches 250 and the groove 270.

Examples of the resist material 290 comprise commonly used photoresist materials, carbon or other organic compounds. FIG. 2B shows an example of a resulting structure.

Thereafter, an etching step is performed so as to remove the upper portion of the resist layer 290. In particular, the resist layer is removed so that an upper surface of the resist layer 290 is disposed beneath a first main surface 210 of the semiconductor body 200.

FIG. 2C shows an example of a resulting structure. Thereafter, the second hard or etching mask layer 240 which may comprise silicon oxide is removed, e.g. by a dry etching process or a wet etching process, e.g. in hydrofluoric acid. This etching step is selective with respect to the resist layer 290. Due to the presence of the silicon nitride layer 230, the silicon oxide 285 in the second groove 280 is protected from etching. Further, due to the presence of the resist layer 290, sticking of the protruding portions 260 during this etching step may be suppressed or avoided.

FIG. 2D shows an example of a resulting structure. Thereafter, the remaining portion of the resist layer 290 is removed. For example, the resist material may be removed by an ashing process of oxidizing the components of the resist layer. FIG. 2E shows an example of a resulting structure.

Thereafter, the silicon nitride hard or etching mask layer 230 is removed, e.g. using a mixture of ethylene glycol and hydrofluoric acid, e.g. at a ratio of EG:HF of more than 90:10, e.g. 96%:4%.

Due to this etching step, the silicon nitride layer 230 is removed from the surface of the workpiece. By suitably setting the time and the temperature of the mixture, the etching rate of etching silicon nitride may be determined. The time and the temperature are set so that mainly the silicon nitride is removed from a resulting surface of the workpiece, while substantially maintaining the silicon body material. Due to this processing, sidewalls 261 of the plurality of protruding semiconductor portions are brought into contact with the mixture of hydrofluoric acid and ethylene glycol.

Thereafter, a further step of forming silicon oxide is performed, e.g. by using a thermal oxidation step or a deposition step. Due to this step, the silicon oxide layer 295 is formed.

FIG. 2F shows an example of a resulting structure. It has been observed that due to the treatment of the surface of the trenches and grooves with the mixture of hydrofluoric acid and ethylene glycol, sticking of the ridges may be prevented.

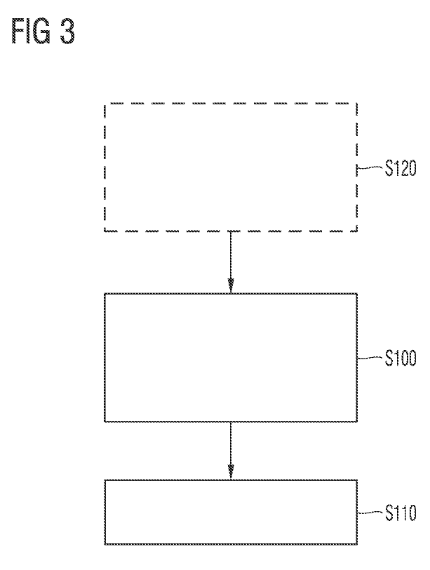

FIG. 3 summarizes the method according to an embodiment.

As is illustrated, a method of manufacturing a semiconductor device comprises forming a plurality of trenches in a semiconductor body thereby defining a plurality of protruding semiconductor portions between adjacent trenches S100, and thereafter, treating the semiconductor body with a mixture of hydrofluoric acid and ethylene glycol S110 and bringing sidewalls of the plurality of protruding semiconductor portions into contact with the mixture of hydrofluoric acid and ethylene glycol. According to an embodiment, the method further comprises forming an etching mask S120 before forming the plurality of trenches, wherein portions of the etching mask are removed by wet etching. According to an embodiment, the method may further comprise forming a protection layer before performing the wet etching step. For example, as has been described with reference to FIGS. 1A to 1F, the protection layer may comprise a silicon nitride layer. The protection layer may be a layer lining the sidewalls of the trenches. The etching mask may e.g. be a photoresist mask.

The method described herein above, may be employed for manufacturing any kind of structures in which a plurality of trenches is arranged in a surface of a semiconductor substrate, and ridges are defined between adjacent trenches. The mixture of hydrofluoric acid and ethylene glycol avoids the occurrence of sticking.

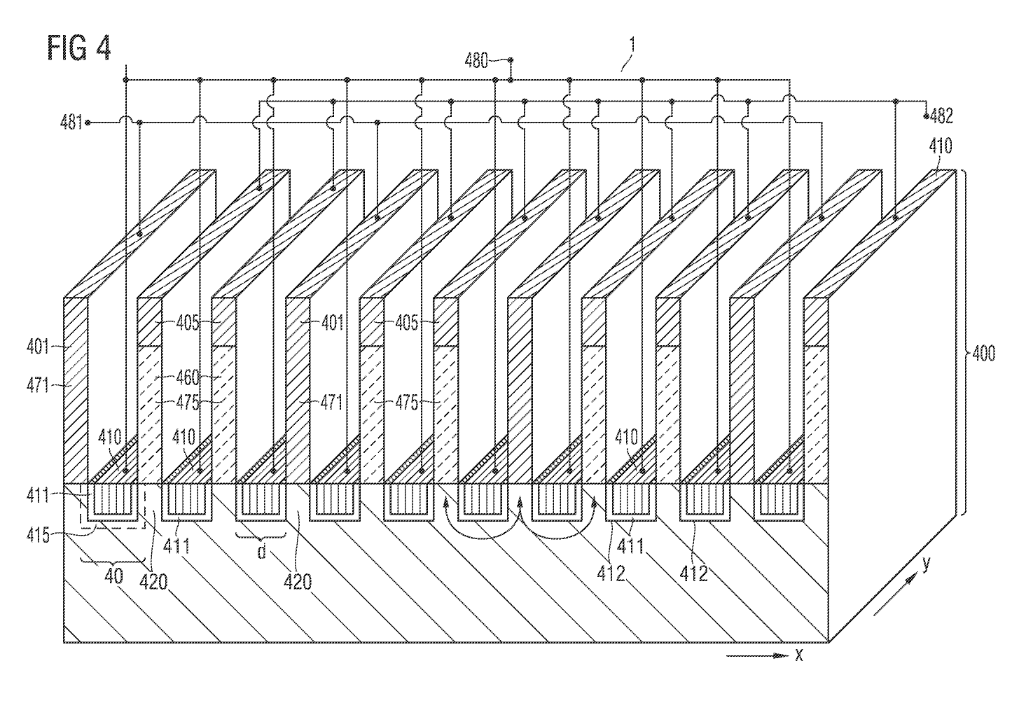

FIG. 4 shows a schematic perspective view of a semiconductor device 1 which may be manufactured using the described method. The semiconductor device is formed in a semiconductor substrate 400 having a first main surface 410. The semiconductor device 1 may be implemented as a power transistor comprising a plurality of transistor cells 40 that may be connected in parallel to each other. The semiconductor device may form part of an ADZFET.

A plurality of thin lamellas or ridges 471, 475 is patterned in the first main surface 410 of the semiconductor substrate. Differently speaking, a plurality of first trenches 412 is arranged in the first main surface 410 of the semiconductor substrate 400. The first trenches 412 run in the second direction, e.g. the y-direction. According to an embodiment, the first trenches 412 may be formed by etching thereby forming the lamellas or ridges 471, 475. According to further embodiments, the lamellas or ridges 471, 475 may be formed by epitaxial growth over a temporary surface of a semiconductor workpiece. For example, the ridges 471, 475 or a portion adjacent to the first main surface of the ridges 471, 475 may be appropriately doped so as to form source regions 401 and drain regions 405.

For example, the ridges may comprise first ridges 471 and second ridges 475. The source region 401 may be arranged in the first ridges 471. According to embodiments, the drain regions 405 may be formed at an upper portion of the second ridges 475 adjacent to the first main surface 410. Further, drift zones 460 may be arranged below the drain regions 405, on a side remote from the first main surface 410.

The source region and the drain region 405 may be doped with dopants of the first conductivity type, e.g. p conductivity type. The drift zone may be doped with dopants of the first conductivity type at a lower doping concentration than the source or the drain region. A gate electrode 410 may be disposed in a lower portion of the first trenches 412. For example, a gate dielectric layer 411 may be disposed between the gate electrode 410 and the adjacent semiconductor material 420. For example, the gate electrode 410 may comprise heavily doped polysilicon or metal. As is shown in FIG. 4, an upper surface of the gate electrode 410 is disposed beneath the first main surface 410. The gate electrode 410 forms a so-called “buried” gate electrode. A lower substrate portion may be doped with dopants of the second conductivity type, so as to form a body region 420.

According to an alternative interpretation, the body region 420 is disposed adjacent to sidewalls of the gate electrode 410. When the transistor is switched on, e.g. by applying a corresponding gate voltage to the gate electrode 410, a conductive inversion layer 415 is formed in the body region 420 adjacent to the gate dielectric layer 411. The conductive inversion layer (conductive channel) 415 is formed at the interface between the body region 420 and the gate dielectric layer 411. Accordingly, the transistor may be in a conductive state from the source region 401 via the conductive channel 415 to the drain region 405 via the drift zone 460. When the transistor is switched off, e.g. by applying a corresponding voltage or no voltage to the gate electrode 410, no conductive inversion layer is formed in the body region 420 and a current flow is blocked. Due to the presence of the drift zone 460 the blocking capability of the transistor may be further improved.

As is illustrated in FIG. 4, one first ridge 471 in which the source region 401 is formed may be followed by two second ridges 475 in which drain regions 405 are arranged. Accordingly, two adjacent transistor cells 40 may share one common source region 401. As has been explained above, the source region may be formed by appropriately doping the semiconductor material of the first ridge 471. According to further embodiments, source regions 401 may be implemented by metal material that may be patterned into the first ridges 471.

The source regions 401 of several transistor cells 40 are electrically connected to a common source terminal 481. Further, the drain regions 405 of a plurality of parallel transistor cells 40 are electrically connected to a common drain terminal 482. Moreover, the gate electrodes 410 of a plurality of parallel transistor cells 40 are electrically connected to a common gate terminal 480.

Generally, a width d of the gate trenches 412 measured along the first direction, e.g. the x-direction may be approximately 100 to 300 nm, e.g. 130 to 180 nm. Further, a depth of the gate trenches may be approximately more than 800 nm, e.g. more than 1 μm, e.g. 1 to 3 μm, for example 1.5 μm. A vertical length of the drift zone may be approximately 1000 nm to 1500 nm. A gate length, i.e. a length of an interface between the body region 420 and the gate dielectric layer 411 in contact with the gate electrode 410 may be approximately 250 to 350 nm. A distance between an upper surface of the gate electrode 410 and the first main surface 410 of the semiconductor substrate 400 may be more than 700 nm and less than 3 μm. e.g. 1 to 2.97 μm.

The method described hereinabove may be used for forming the gate trenches 412.

According to further embodiment, a semiconductor device which may be manufactured using the method described hereinabove may be a microelectromechanical (“MEMS”) device such as a sensor, an actuator, a microphone. According to further embodiments, the semiconductor device may be a nanoelectromechanical device.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A method of manufacturing a semiconductor device, the method comprising:
forming an etching mask over a semiconductor body;
forming a plurality of trenches in the semiconductor body to define a plurality of protruding semiconductor portions between adjacent trenches;
forming a protection layer in contact with a semiconductor material of the protruding semiconductor portions;
performing a wet etching step to remove portions of the etching mask; and
thereafter, treating the semiconductor body with a mixture of hydrofluoric acid and ethylene glycol and bringing the semiconductor material of sidewalls of the plurality of protruding semiconductor portions into contact with the mixture of hydrofluoric acid and ethylene glycol.

2. The method of claim 1, wherein a composition ratio of the mixture of ethylene glycol and hydrofluoric acid is more than 90:10.

3. The method of claim 1, wherein the etching mask is a hard mask.

4. The method of claim 1, wherein the etching mask comprises a resist material.

5. The method of claim 1, wherein the protection layer is a layer lining the sidewalls of the trenches.

6. The method of claim 1, wherein the protection layer comprises silicon nitride.

7. The method of claim 1, wherein the protection layer is removed by treating the semiconductor body with the mixture of hydrofluoric acid and ethylene glycol.

8. The method of claim 1, wherein the protection layer fills the trenches.

9. The method of claim 8, wherein the protection layer comprises a resist material.

10. The method of claim 8, wherein the protection layer comprises an organic material.

11. The method of claim 1, further comprising forming a silicon oxide layer after treating the semiconductor body with the mixture.

12. The method of claim 1, wherein the trenches have a depth of more than 1 μm.

13. The method of claim 1, wherein a width of the protruding portions is less than 500 nm.

14. The method of claim 1, wherein an aspect ratio of height to width of the protruding portions is more than 20.

15. The method of claim 1, wherein the plurality of trenches comprises more than 1000 trenches.

16. The method of claim 1, wherein a portion of the etching mask is removed by treating the semiconductor body with the mixture of hydrofluoric acid and ethylene glycol.

17. A semiconductor device manufactured by the method of claim 1.

18. The semiconductor device of claim 17, wherein the semiconductor device is selected from the group consisting of a power transistor, a micromechanical system, a nanomechanical system, a sensor, and an actuator.

19. A semiconductor device, comprising:
a semiconductor substrate having a first main surface;
a plurality of ridges patterned in the first main surface of the semiconductor substrate;
a source region arranged in each first one of the ridges;
a drain region arranged at an upper portion of each second one of the ridges;
drift zones arranged below the drain regions, on a side remote from the first main surface;
a gate electrode arranged in first trenches between the first and the second ridges;
a gate dielectric layer arranged between each gate electrode and adjacent semiconductor material of the semiconductor substrate; and
a body region arranged between adjacent ones of the trenches.

20. The semiconductor device of claim 19, wherein the body regions are disposed adjacent to sidewalls of the first trenches.

21. The semiconductor device of claim 19, wherein one first ridge in which a source region is arranged is followed by two second ridges in which drain regions are arranged so that two adjacent transistor cells share one common source region.

22. The semiconductor device of claim 19, wherein the source regions comprise doped semiconductor material of the first ridges.

23. The semiconductor device of claim 19, wherein the source regions comprise metal material patterned into the first ridges.
